(19) United States
(12) Patent Application Publication
(10) Pub. No.: US 2023/0080753 A1
(43) Pub. Date: Mar. 16, 2023

(54) PELLICLE, AND PRODUCTION METHOD THEREFOR

(71) Applicant: MITSUI CHEMICALS, INC., Minato-ku, Tokyo (JP)

(72) Inventors: Yasushi SATOH, Sodegaura-shi, Chiba (JP); Kazuo KOHMURA, Iwakuni-shi, Yamaguchi (JP); Akira ISHIKAWA, Ichihara-shi, Chiba (JP); Takashi UNEZAKI, Ichihara-shi, Chiba (JP); Hisako ISHIKAWA, Ichihara-shi, Chiba (JP); Takashi KOZEKI, Ichihara-shi, Chiba (JP); Ken ITO, Hiroshima-shi, Hiroshima (JP)

(73) Assignee: MITSUI CHEMICALS, INC., Minato-ku, Tokyo (JP)

(21) Appl. No.: 17/801,430

(22) PCT Filed: Mar. 24, 2021
(86) PCT No.: PCT/JP2021/012118

§ 371 Date: Aug. 22, 2022

(30) Foreign Application Priority Data
Mar. 27, 2020 (JP) 2020-057395

(51) Int. Cl. G03F 1/64

(52) U.S. Cl. CPC G03F 1/64

(57) ABSTRACT

The purpose of the present disclosure is to provide a pellicle that has an adhesive layer having good flatness, and a method for producing the pellicle with good reproducibility. Said purpose is achieved by a pellicle having: a pellicle frame; a pellicle film provided so as to be stretched on one end surface of the pellicle frame; and an adhesive layer provided on the other end surface of the pellicle frame. The adhesive layer contains a cured product of a resin composition containing a curable polymer (A), and a curing agent (B1) and a curing agent (B2). The curing agent (B1) and the curing agent (B2) have different curing conditions.

### TECHNICAL FIELD

The present disclosure relates to a pellicle used for protecting a lithography mask from dust in the lithography process for semiconductor devices, such as LSIs and VLSIs, liquid crystal display panels, and the like, and a method for producing the same.

### BACKGROUND ART

In the lithography process for semiconductor devices, such as LSIs and VLSIs, liquid crystal display panels, and the like, a pellicle is mounted on a lithography mask for preventing attachment of foreign matter to the mask. A pellicle usually includes a pellicle frame, a transparent pellicle membrane stretched over the upper end surface of the pellicle frame, and an adhesive layer provided on the lower end surface of the pellicle frame for sticking the pellicle to a mask. Sticking a pellicle having a distortion to a mask distorts the mask to thereby displace the exposure position. Thus, pellicles having no distortion have been required. Accordingly, the adhesive layer of the pellicle is required to have flatness and stress relaxation properties.

In recent years, reduction in the wavelength of exposure light has advanced with the miniaturization of mask patterns. Examples of short-wavelength light include excimer light, such as KrF excimer laser and ArF excimer laser. Such short-wavelength light has high energy, and thus, the components of the adhesive are likely to be decomposed during exposure. The decomposition of the adhesive components may lead to problems such as release of the pellicle from the mask in the exposure process.

Examples of adhesives known for use in the adhesive layer of pellicles include rubber or polyurethane adhesives, silicone adhesives as described in Patent Literature 1, and acrylic adhesives as described in Patent Literature 2. For example, Patent Literature 2 discloses a pellicle that includes an adhesive layer of a thickness of 400 μm or more, the adhesive layer containing a thermal radical polymerization initiator.

### CITATION LIST

### Patent Literature

### PTL 1

Japanese Patent Application Laid-Open No. 05-281711

### PTL 2

Japanese Patent Application Laid-Open No. 2006-146085

### SUMMARY OF INVENTION

### Technical Problem

In Patent Literature 2, the thickness of the adhesive layer is as large as 400 μm or more. With such a large thickness, the flatness of the adhesive layer tends to deteriorate. Thus, a distortion is likely occur in the pellicle, and sticking the pellicle often distorts the mask.

Conventional adhesive layers of pellicles are often formed of a resin composition containing one curing agent. When a coating film having a large thickness is formed with such a resin composition, it has been difficult to cure the coating film so as to have a moderate hardness after curing at which flattening can be achieved. For example, the coating film is completely cured and cannot be collapsed in the flattening process. Alternatively, the coating film is soft due to insufficient curing and may be collapsed more than required in the flattening process to thereby protrude outside the frame. Thus, it has been difficult to produce a pellicle that includes an adhesive layer having favorable flatness with high reproducibility, and even if flattening has been achieved, the adhesive layer has variations in thickness.

Accordingly, an object of the present disclosure is to provide a pellicle that includes an adhesive layer having favorable flatness, and a method for producing the pellicle with high reproducibility.

### Solution to Problem

The present disclosure relates to a pellicle below.

[1] A pellicle, comprising: a pellicle frame; a pellicle membrane stretched over one end surface of the pellicle frame; and an adhesive layer provided on another end surface of the pellicle frame, wherein the adhesive layer comprises a cured product of a resin composition comprising a curable polymer (A), a curing agent (B1), and a curing agent (B2) different from the curing agent (B1).
[2] The pellicle according to [1], wherein the curing agent (B1) and the curing agent (B2) are radical polymerization initiators.
[3] The pellicle according to [2], wherein the curing agent (B1) is a thermal radical polymerization initiator, and the curing agent (B2) is a photoradical polymerization initiator.
[4] The pellicle according to [3], wherein the thermal radical polymerization initiator is a peroxide radical polymerization initiator or azo radical polymerization initiator.
[5] The pellicle according to any one of [1] to [4], wherein the curable polymer (A) is at least one curable polymer selected from the group consisting of a (meth)acrylic acid ester copolymer (A-1), an organopolysiloxane (A-2), and a polyurethane polyol (A-3).
[6] The pellicle according to [5], wherein the curable polymer (A) is a (meth)acrylic acid ester copolymer.
[7] The pellicle according to [6], wherein the curable polymer (A) has a side chain containing a carbon-carbon multiple bond-containing group.
[8] The pellicle according to any one of [1] to [7], wherein the carbon-carbon multiple bond-containing group is a carbon-carbon double bond-containing group.
[9] The pellicle according to [8], wherein a multiple bond equivalent of the curable polymer (A) is 156 g/mol or more and 100,000 g/mol or less.
[10] The pellicle according to any one of [1] to [9], wherein the curable polymer (A) has a weight average molecular weight of 10,000 or more and 1,000,000 or less.
[11] The pellicle according to any one of [1] to [10], wherein the resin composition further comprises a crosslinking agent (C).
[12] The pellicle according to [11], wherein the crosslinking agent (C) is a compound having a polyfunctional carbon-carbon multiple bond.

The present disclosure further relates to a method for producing a pellicle below.

[13] A method for producing the pellicle according to any one of [1] to [11], comprising: stretching a pellicle membrane over one end surface of a pellicle frame; applying a resin composition comprising a curable polymer (A), a curing agent (B1); and a curing agent (B2) different from the curing agent (B1) on another end surface of the pellicle frame; and subjecting the applied resin composition to photocuring treatment and thermal curing treatment, and flattening treatment to thereby provide an adhesive layer.

### Advantageous Effects of Invention

According to the present disclosure, a pellicle that includes an adhesive layer having favorable flatness and a method for producing the same can be provided.

### DESCRIPTION OF EMBODIMENTS

The present inventors have studied thoroughly, in order to overcome the problems, to have found that, when the adhesive layer of a pellicle includes a cured product of a resin composition that contains a curable polymer and at least two curing agents each having different curing conditions, the flatness is favorable. The reason is uncertain, but is presumed as follows.

When at least 2 curing agents each having different curing conditions are contained in a resin composition for use in forming the adhesive layer of a pellicle, the degree of curing of a coating film containing the resin composition can be modulated by adjusting the type and amount of the curing agents to be used and further conducting a multi-stage curing process in accordance with the curing agents. As a result, flattening can be achieved without excessively collapsing the adhesive layer, and furthermore, the thickness of the adhesive layer can be easily made to be uniform.

1. Pellicle

The pellicle of the present disclosure includes a pellicle frame, a pellicle membrane stretched over one end surface of the pellicle frame, and an adhesive layer provided on the other end surface of the pellicle frame.

1-1. Pellicle Frame

The pellicle frame may be a pellicle frame usually used. Examples of the material for the pellicle frame include aluminum alloys, stainless steel, polyethylene, and black anodized aluminum. Of these, aluminum alloys, black anodized aluminum or the like are preferable because of light weight and the like.

1-2. Pellicle Membrane

The pellicle membrane is fixed to one opening of the pellicle frame. The pellicle membrane may be a pellicle membrane usually used. Examples of the material for the pellicle membrane include nitrocellulose, ethyl cellulose, cellulose acetate, cellulose propionate, pullulan compounds, amorphous fluorine polymers, and silicone-modified polyvinyl alcohol. Of these, preferred are amorphous fluorine polymers having sufficient resistance to excimer light.

1-3. Adhesive Layer

The adhesive layer includes a cured product of a resin composition comprising a curable polymer (A), a curing agent (B1), and a curing agent (B2) different from the curing agent (B1).

[Curable Polymer (A)]

The curable polymer (A) is a polymer that is cured by application of light or heat in the presence of the curing agent (B1) or the curing agent (B2). The curable polymer (A) is only required to have a functional group reactive with the curing agent (B1) and a functional group reactive with the curing agent (B2) (these may be the same functional groups or may be different functional groups in accordance with the curing agents) in the molecule, and can be a polymer having a carboxy group, a hydroxyalkyl group, or a group that contains a carbon-carbon multiple bond in the molecule, for example. The type of the curable polymer (A) is not limited, and any curable polymer may be acceptable. Examples of the curable polymer (A) include (meth)acrylic acid ester copolymers (A-1), organopolysiloxanes (A-2), and polyurethane polyols (A-3). Of these, (meth)acrylic acid ester copolymers (A-1) are preferable because of high heat resistance and light resistance and of being not likely to be decomposed.

From the viewpoint of being cured by a photoinitiator or thermal initiator, the curable polymer (A) preferably has a group that contains a carbon-carbon multiple bond.

(Carbon-Carbon Multiple Bond-Containing Group)

The carbon-carbon multiple bond-containing group is not particularly limited as long as being a group that contains a carbon-carbon double bond and/or carbon-carbon triple bond. Polymerizable carbon-carbon multiple bonds mean ethylenic and alkynic carbon-carbon multiple bonds.

The carbon-carbon double bond-containing group is not particularly limited as long as being a group that contains a carbon-carbon double bond. Examples thereof include functional groups obtained by polymerizing polyethylene glycol #600 diacrylate, isoprene, diallyl ether, divinylbenzene (such as a (meth)acryloyl group, a vinyl group, an allyl group, and a styryl group). The carbon-carbon triple bond-containing group is not particularly limited as long as being a group that contains a carbon-carbon triple bond. Examples thereof include functional groups obtained by polymerizing hexane-1,5-diyne, diethynyl benzene, and diethylene glycol bis(2-propynyl)ether. Of these, from the viewpoint of more excellent stability and reactivity of radicals and a sufficiently larger decrease in the pressure-adhesive strength after heating, a (meth)acryloyl group, which is a carbon-carbon double bond-containing group, is preferable.

In the present disclosure, the expression “(meth)acryl”, as used herein, is intended to mean both or one of “acryl” and “methacryl”, and “(meth)acryloyl” is also intended to have the same meaning.

The curable polymer (A) may have a multiple bond-containing group on any of side groups and ends, and has one preferably in a side group, from the viewpoint of improvement in the reactivity of the polymerizable carbon-carbon multiple bond and a sufficiently larger decrease in the pressure-adhesive strength after heating or UV-curing.

A curable polymer (A) having a multiple bond-containing group introduced on a side chain also can be obtained, for example, by an approach in which a precursor polymer having a hydroxy group and a carboxy group on side groups is provided, and an isocyanate compound or epoxy compound having a multiple bond is allowed to react with the hydroxy group and the carboxy group of the precursor polymer.

The range of the multiple bond equivalent representing the content of the multiple bond-containing group in the curable polymer (A) is preferably 156 g/mol or more and 100,000 g/mol or less, more preferably 500 g/mol or more and 50,000 g/mol or less, even more preferably 1,000 g/mol or more and 20,000 g/mol or less. When the content of the multiple bond-containing group is within the range described above, it is possible to design a pressure-adhesive strength after curing by heating or UV irradiation ranging from weak to strong pressure adhesion and to more sufficiently reduce an adhesive residue.

The multiple bond equivalent, which is the mass of the solid content (g) of the curable polymer (A) with respect to the total number of moles (mol) of the multiple bonds (that is, the double bond and triple bond) possessed by the curable polymer (A), can be represented by the following expression:

Multiple bond equivalent (g/mol)=mass of solid content in curable polymer (A) (g)/number of moles of multiple bonds of the curable polymer (A).

The mass of the solid content of the curable polymer (A) referred to herein is the average molecular weight (Mw) of the curable polymer (A). The number of moles of the multiple bond of the curable polymer (A) is the number of moles of the compound having the polymerizable multiple bond group located on a side chain.

The weight average molecular weight (Mw) of the curable polymer (A) is a weight average molecular weight in terms of polystyrene determined by GPC. A method for measuring the weight average molecular weight will be described below.

The number of moles of the multiple bonds of the curable polymer (A) can be calculated from the integral of ¹H-NMR. For example, a solution obtained by adding a standard reagent (such as styrene) in an optional amount (for example, 0.1 mmol) to the curable polymer (A) is provided, and diluted with a deuterated solvent (for example, CDCl₃) to prepare a sample solution. The adjusted sample solution is subjected to ¹H-NMR measurement to obtain a spectrum. Regarding the spectrum obtained, the number of moles of the multiple bonds can be obtained from the integral of the peaks derived from the standard reagent and the integral of the peaks derived from the multiple bonds included in the curable polymer (A).

(Weight Average Molecular Weight (Mw))

The weight average molecular weight of the curable polymer (A) is preferably within the range of 10,000 or more and 1,000,000 or less, more preferably of 30,000 or more and 100,000 or less. A weight average molecular weight within the range described above is preferable because the cohesion and the adhesive strength of the adhesive layer become moderate and an adhesive residue is unlikely to occur.

The weight average molecular weight is a weight average molecular weight (Mw) in terms of polystyrene determined by gel permeation chromatography (GPC).

The lower limit of the molecular weight distribution of the curable polymer (A), that is, the ratio of Mw with respect to the number average molecular weight (Mn) in terms of polystyrene determined by GPC (Mw/Mn), is usually 1, preferably 1.1. The upper limit of the ratio described above is preferably 5, more preferably 3, even more preferably 2, particularly preferably 1.7. When the molecular weight distribution is within the range described above, the degree of crosslinking can be controlled, control of functional groups, which are said to be unfavorable for an adhesive residue, is improved, and thus, the adhesive residue is reduced.

In the present disclosure, the conditions for GPC used for measurement of the Mw and Mn of the curable polymer (A) include the following.

GPC column: 2 columns of “TSKgel Multipore HXL-M”, TOSOH CORPORATION, for example

Column temperature: 40° C.

Elution solvent: tetrahydrofuran (Wako Pure Chemical Industries, Ltd.)

Flow rate: 1.0 mL/minute

Sample concentration: 0.05 mass %

Amount of sample injected: 100 μL

Detector: differential refractometer

Standard substance: monodispersed polystyrene

((Meth)Acrylic Acid Ester Copolymer (A-1))

In the present disclosure, the “(meth)acrylic acid ester copolymer (A-1) preferably includes a (meth)acrylic acid alkyl ester having an alkyl group having 1 to 14 carbon atoms and a reactive monomer having a functional group reactive with a curing agent (B) to be mentioned below, as monomer units.

Specific examples of the (meth)acrylic acid alkyl ester having an alkyl group having 1 to 14 carbon atoms include (meth)acrylic acid esters of linear aliphatic alcohols such as butyl (meth)acrylate, hexyl (meth)acrylate, octyl (meth)acrylate, decyl (meth)acrylate, dodecyl (meth)acrylate, and lauryl (meth)acrylate, isobutyl (meth)acrylate, isoamyl (meth)acrylate, 2-ethylhexyl (meth)acrylate, isooctyl (meth)acrylate, isononyl (meth)acrylate, methyl (meth)acrylate, ethyl (meth)acrylate, propyl (meth)acrylate, and isopropyl (meth)acrylate. These may be used singly or in combination of two or more thereof. Of these, it is preferable to use a combination of two: a (meth)acrylic acid alkyl ester having an alkyl group having 1 to 3 carbon atoms; and a (meth)acrylic acid alkyl ester having an alkyl group having 4 to 14 carbon atoms. Examples thereof include combinations of methyl (meth)acrylate, ethyl (meth)acrylate, propyl (meth)acrylate, or isopropyl (meth)acrylate with butyl (meth)acrylate or octyl (meth)acrylate.

Examples of the reactive monomer having a functional group reactive with a curing agent include carboxyl group-containing monomers such as (meth)acrylic acid, itaconic acid, maleic acid, and crotonic acid, hydroxyl group-containing monomers such as 2-hydroxyethyl (meth)acrylate, 3-hydroxypropyl (meth)acrylate, 2-hydroxypropyl (meth)acrylate, and 4-hydroxybutyl (meth)acrylate, and monomers into which a carbon-carbon multiple bond-containing group may be introduced to be mentioned below (for example, polyfunctional monomers). These monomers may be used singly or in combination of two or more thereof. Of these, hydroxyl group-containing (meth)acrylates having a hydroxyalkyl group having 2 to 4 carbon atoms such as 2-hydroxyethyl (meth)acrylate and 4-hydroxybutyl (meth)acrylate, and carboxyl group-containing monomers such as (meth)acrylic acid are preferable from the viewpoint of copolymerizability, versatility, and the like. Particularly from the viewpoint of reduction in the adhesive residue, (meth)acrylic acid is preferable.

The (meth)acrylic acid ester copolymer (A-1) is preferably a polymer that has a structural unit derived from a (meth)acrylic acid ester (hereinafter, also referred to as the “structural unit (I)”) and a side chain containing a carbon-carbon multiple bond-containing group. The (meth)acrylic acid ester copolymer (A-1) preferably further has a structural unit containing a hydroxy group (hereinafter, also referred to as the “structural unit (II)”), in addition to the structural unit (I). The copolymer (A-1) may have other structural units in addition to the structural units (I) to (II).

The carbon-carbon multiple bond-containing group may be contained in the structural unit (II) or other structural units. Hereinbelow, the carbon-carbon multiple bond-containing group and each of the structural units will be described.

(Structural Unit (I))

The structural unit (I) is a structural unit derived from a (meth)acrylic acid ester. The structural unit (I) has a structure represented by —CH₂—CH(COOCH₃)—.

The structural unit (I) is preferably a structural unit derived from a (meth)acrylic acid alkyl ester containing an alkyl group having 4 or more and 10 or less carbon atoms. Examples of the alkyl group having 4 or more and 10 or less carbon atoms include a n-butyl group, a n-pentyl group, a n-hexyl group, a n-octyl group, a 2-ethylhexyl group, and a n-decyl group. Of these, a n-butyl group and a 2-ethylhexyl group are preferable.

Further, preferable is a structural unit (I) from which a leaving product is derived will be a compound having a boiling point of 150° C. or less. For example, when the structural unit (I) is butyl acrylate, the leaving product is butanol having a boiling point of 117° C. When the leaving product has a boiling point of 150° C. or less, outgassing is easily removed. Examples of the structural unit (I) generating a leaving product having a boiling point of 150° C. or less include (meth)acrylic acid esters in which the ester group has 5 or less carbon atoms such as methyl (meth)acrylate, ethyl (meth)acrylate, propyl (meth)acrylate, and isopropyl (meth)acrylate.

When the (meth)acrylic acid ester copolymer (A-1) has the structural unit (I), the lower limit of content of the structural unit (I) is preferably 5 mass %, more preferably 10 mass %, even more preferably 30 mass %, particularly preferably 40 mass % based on the total mass of the (meth)acrylic acid ester copolymer (A-1). The upper limit of the content described above is preferably 95 mass %, more preferably 80 mass %, even more preferably 70 mass %, particularly preferably 60 mass % based on the total mass of the (meth)acrylic acid ester copolymer (A-1). When the content of the structural unit (I) is within the range described above, the strength of the adhesive layer can be further improved, and consequently, the pressure-adhesive strength can be further improved. When the content of the structural unit (I) is within the range described above, it is possible to design a pressure-adhesive strength ranging from weak to strong pressure adhesion and to more sufficiently reduce the adhesive residue.

(Structural Unit (II))

The structural unit (II) is a structural unit containing a hydroxy group. When the (meth)acrylic acid ester copolymer (A-1) has the structural unit (II), the pressure-adhesive strength is further improved.

Examples of the hydroxy group include an alcoholic hydroxy group. Of these, an alcoholic hydroxy group is preferable from the viewpoint of reduction in the adhesive residue.

Examples of the monomer providing the structural unit (II) include hydroxyalkyl (meth)acrylates such as hydroxyethyl (meth)acrylate, hydroxypropyl (meth)acrylate, and hydroxybutyl (meth)acrylate; and hydroxyaryl (meth)acrylates such as hydroxyphenyl (meth)acrylate and hydroxynaphthyl (meth)acrylate. Of these, hydroxyalkyl (meth)acrylates are preferable, hydroxyalkyl acrylates are more preferable, and hydroxyethyl acrylate is even more preferable.

When the (meth)acrylic acid ester copolymer (A-1) has the structural unit (II), the lower limit of the content of the structural unit (II) is preferably 1 mass %, more preferably 3 mass %, even more preferably 4 mass %, particularly preferably 5 mass % based on the total mass of the (meth)acrylic acid ester copolymer (A-1). The upper limit of the content described above is preferably 30 mass %, more preferably 25 mass %, even more preferably 15 mass %, particularly preferably 10 mass % based on the total mass of the (meth)acrylic acid ester copolymer (A-1).

(Organopolysiloxane (A-2))

Examples of the organopolysiloxane that can be used include dimethylpolysiloxane, methylphenylpolysiloxane, fluoropolysiloxane, tetramethyltetraphenylpolysiloxane, and methylhydrogenpolysiloxane. These preferably each include a functional group reactive with the curing agent (B1) and a functional group reactive with the curing agent (B2) (these may be the same functional groups or may be different functional groups in accordance with the curing agents) introduced into the molecule thereof by means of epoxy modification, alkyl modification, amino modification, carboxyl modification, alcohol modification, epoxy polyether modification, or the like. Of these, an acryl-modified dimethylpolysiloxane is preferably used.

(Polyurethane Polyol (A-3))

A polyurethane polyol is obtained by at least allowing a polyisocyanate to react with a polyol component. The polyurethane polyol preferably includes a functional group reactive with the curing agent (B1) and a functional group reactive with the curing agent (B2) (these may be the same functional groups or may be different functional groups in accordance with the curing agents) introduced into the molecule thereof.

Examples of the polyisocyanate include aromatic polyisocyanates, araliphatic polyisocyanates, and aliphatic polyisocyanates (including alicyclic polyisocyanates).

Examples of aromatic polyisocyanates include aromatic diisocyanates such as 4,4′-, 2,4′-, or 2,2′-diphenylmethane diisocyanate or mixtures thereof (MDI), 2,4- or 2,6-tolylene diisocyanate or mixtures thereof (TDI), 4,4′-toluidine diisocyanate (TODI), 1,5-naphthalene diisocyanate (NDI), m- or p-phenylene diisocyanate or mixtures thereof, 4,4′-diphenyl diisocyanate, and 4,4′-diphenylether diisocyanate.

Examples of araliphatic polyisocyanates include araliphatic diisocyanates such as 1,3- or 1,4-xylylene diisocyanate or mixtures thereof (XDI), 1,3- or 1,4-tetramethylxylylene diisocyanate or mixtures thereof (TMXDI), and ω,ω′-diisocyanate-1,4-diethyl benzene.

Examples of aliphatic polyisocyanates include aliphatic diisocyanates such as hexamethylene diisocyanate (HDI), trimethylene diisocyanate, tetramethylene diisocyanate, 1,5-pentamethylene diisocyanate, 1,2-, 2,3-, or 1,3-butylene diisocyanate, and 2,4,4- or 2,2,4-trimethylhexamethyl ene diisocyanate.

Examples of aliphatic polyisocyanates further include alicyclic polyisocyanates.

Examples of alicyclic polyisocyanates include alicyclic diisocyanates such as 3-isocyanatomethyl-3,5,5-trimethylcyclohexylisocyanate (isophorone diisocyanate, IPDI), 4,4′-, 2,4′-, or 2,2′-dicyclohexylmethane diisocyanate or mixtures thereof (H12MDI), 1,3- or 1,4-bis(isocyanatomethyl)cyclohexane or mixtures thereof (hydrogenated xylylene diisocyanate, H6XDI), bis(isocyanatomethyl)norbornane (NBDI), 1,3-cyclopentene diisocyanate, 1,4-cyclohexanediisocyanate, 1,3-cyclohexanediisocyanate, methyl-2,4-cyclohexanediisocyanate, and methyl-2,6-cyclohexanediisocyanate.

As the polyisocyanate, modified products of the polyisocyanates described above can be used. Examples of such modified products include multimers of the polyisocyanate described above (for example, dimers, trimers, pentamers, and heptamers), and, for instance, biuret-modified products formed by a reaction of the above-described polyisocyanate or multimer with water, allophanate-modified products formed by a reaction of the polyisocyanate or multimer with a monool or polyhydric alcohol (mentioned below), oxadiazinetrione modified products formed by a reaction thereof with carbon dioxide, and further, polyol-modified products formed by a reaction thereof with a low molecular weight polyol (mentioned below).

These polyisocyanates may be used singly or in combination of two or more thereof.

Examples of the polyol component include polyether polyols, polyester polyols, and polycarbonate polyols.

Examples of polyether polyols include polyoxyalkylene polyols and polytetramethylene ether glycol.

Examples of polyoxyalkylene polyols include addition polymers of alkylene oxides obtained by use of a low molecular weight polyol or low molecular weight polyamine as an initiator.

Examples of alkylene oxides include propylene oxide, ethylene oxide, butylene oxide, and styrene oxide. These alkylene oxides may be used singly or in combination of two or more thereof. Of these, preferable examples include propylene oxide and ethylene oxide.

[Curing Agent (B1) and Curing Agent (B2)]

The types of the curing agent (B1) and curing agent (B2) used for the resin composition are not particularly limited as long as both the curing agents can cure the curable polymer (A) to be used. The curing agent (B1) and curing agent (B2) are only required to be different in curing conditions, and the curing agent (B1) and curing agent (B2) can be optionally determined. In the present disclosure, the curing agent that is contained in the largest amount in the adhesive is denoted as the curing agent (B1), and the curing agent that is contained in the lesser amount is denoted as the curing agent (B2). It is only required that at least two curing agents: the curing agent (B1) and curing agent (B2) be used, and other curing agents may be further included.

Examples of the curing agent (B1) and curing agent (B2) include radical polymerization initiators. Examples of radical polymerization initiator that can be used include photoradical polymerization initiators and thermal radical polymerization initiators.

A thermal radical polymerization initiator refers to a compound that generates radicals by heat, that is, a compound that absorbs thermal energy and decomposes the energy to generate radical species. A photoradical polymerization initiator refers to a compound that generates radicals on light irradiation, that is, a compound that absorbs light energy and decomposes the energy to generate radical species. In the present disclosure, both the curing agents (B1) and (B2) are preferably radical polymerization initiators because use of initiators that generate radicals in combination allows polymerization reaction of multiple bonds included in the curable polymer (A) to rapidly occur, the degree of polymerization to increase, and curing to be easily achieved. When radical polymerization initiators are used as the curing agents (B1) and (B2), at least two different photoradical polymerization initiators or at least two different thermal radical polymerization initiators may be used, or a thermal radical polymerization initiator and a photoradical polymerization initiator may be used in combination. In order to flatten the adhesive layer to make its thickness uniform, it is preferable that a thermal radical polymerization initiator be used as the curing agent (B1) and a photoradical polymerization initiator be used as the curing agent (B2).

As the thermal radical polymerization initiator to be used as the curing agent (B1), a peroxide radical polymerization initiator or azo radical polymerization initiator is preferable.

Specific examples of the peroxide radical polymerization initiator can include the following compounds and commercially available products: diisobutyryl peroxide, cumyl peroxyneodecanoate, di-n-propyl peroxydicarbonate, diisopropyl peroxydicarbonate, di-sec-butylperoxydicarbonate, 1,1,3,3-tetramethylbutyl peroxyneodecanoate, di(4-t-butylcyclohexyl) peroxydicarbonate, di(2-ethylhexyl) peroxydicarbonate, t-hexyl peroxyneodecanoate, t-butyl peroxyneodecanoate, t-butyl peroxyneoheptanoate, t-hexyl peroxypivalate, t-butyl peroxypivalate, di(3,5,5-trimethylhexanoyl)peroxide, dilauroyl peroxide, 1,1,3,3-tetramethylbutyl peroxy-2-ethylhexanoate, disuccinic acid peroxide, 2,5-dimethyl-2,5-di(2-ethylhexanoyl peroxy)hexane, t-hexyl peroxy-2-ethylhexanoate, di(4-methylbenzoyl)peroxide, t-butyl peroxy-2-ethylhexanoate, di(3-methylbenzoyl)peroxide, benzoyl(3-methylbenzoyl)peroxide, dibenzoyl peroxide, dibenzoyl peroxide, 1,1-di(t-butylperoxy)-2-methylcyclohexane, 1,1-di(t-hexylperoxy)-3,3,5-trimethylcyclohexane, 1,1-di(t-hexylperoxy)cyclohexane, 1,1-di(t-butylperoxy)cyclohexane, 2,2-di[4,4-di-(t-butylperoxy)cyclohexyl]propane, t-hexyl peroxyisopropyl monocarbonate, t-butyl peroxymalate, t-butylperoxy-3,5,5-trimethylhexanoate, t-butylperoxy laurate, t-butylperoxy isopropyl monocarbonate, t-butylperoxy-2-ethylhexyl monocarbonate, t-hexyl peroxybenzoate, 2,5-dimethyl-2,5-di(benzoylperoxy)hexane, t-butylperoxy acetate, 2,2-di(t-butylperoxy)butane, t-butylperoxy benzoate, n-butyl-4,4-di-t-butylperoxy valerate, di(2-t-butylperoxyisopropyl)benzene, dicumyl peroxide, di-t-hexyl peroxide, 2,5-dimethyl-2,5-di(t-butylperoxy)hexane, t-butylcumyl peroxide, di-t-butyl peroxide, p-methane hydroperoxide, 2,5-dimethyl-2,5-di(t-butylperoxy)hexan-3-yne, diisopropylbenzene hydroperoxide, 1,1,3,3-tetramethylbutyl hydroperoxide, cumene hydroperoxide, t-butyl hydroperoxide, 2,4-dichlorobenzoyl peroxide, o-chlorobenzoyl peroxide, p-chlorobenzoyl peroxide, tris(t-butylperoxy)triazine, 2,4,4-trimethylpentyl peroxyneodecanoate, α-cumyl peroxyneodecanoate, t-amyl peroxy 2-ethylhexanoate, t-butyl peroxyisobutyrate, di-t-butyl peroxyhexahydroterephthalate, di-t-butyl peroxytrimethyladipate, di-3-methoxybutyl peroxydicarbonate, diisopropyl peroxydicarbonate, t-butylperoxyisopropyl carbonate, 1,6-bis(t-butylperoxycarbonyloxy)hexane, diethylene glycol bis(t-butylperoxycarbonate), and t-hexyl peroxyneodecanoate.

Examples thereof include ketone peroxides such as PERHEXA H, peroxyketals such as PERHEXA TMH, hydroperoxides such as PERBUTYL H-69, dialkyl peroxides such as PERCUMYL D, PERBUTYL C, PERBUTYL D, and PERBUTYL O, diacyl peroxides such as NYPER BW, peroxy esters such as PERBUTYL Z and PERBUTYL L, and peroxy dicarbonates such as PEROYL TCP, commercially available from NOF CORPORATION.

Further examples include Trigonox 36-C75, Laurox, Perkadox L-W75, Perkadox CH-50L, Trigonox TMBH, Kayacumene H, Kayabutyl H-70, Perkadox BC-FF, Kayahexa AD, Perkadox 14, Kayabutyl C, Kayabutyl D, Perkadox 12-XL25, Trigonox 22-N70 (22-70E), Trigonox D-T50, Trigonox 423-C70, Kayaester CND-C70, Trigonox 23-C70, Trigonox 257-C70, Kayaester P-70, Kayaester TMPO-70, Trigonox 121, Kayaester O, Kayaester HTP-65W, Kayaester AN, Trigonox 42, Trigonox F-C50, Kayabutyl B, Kayacarbon EH, Kayacarbon I-20, Kayacarbon BIC-75, Trigonox 117, and Kayalene 6-70, manufactured by Kayaku Akzo Co., Ltd.

The peroxide radical polymerization initiators described above may be used singly or may be used in combination of a plurality thereof.

Examples of the azo radical polymerization initiator include compounds having an azo group such as azonitrile compounds, azoester compounds, azoamide compounds, azoamidine compounds, azoimidazoline compounds, and polymeric azo compounds.

Examples of the polymeric azo compound include trade names VPE-0201, VPE-0401, VPE-0601, and VPS-1001 (all manufactured by Wako Pure Chemical Industries, Ltd.).

The azo radical polymerization initiators described above may be used singly or may be used in combination of a plurality thereof.

The 10-hour half-life temperature of the radical polymerization initiator is preferably from 50° C. to 150° C., more preferably from 60° C. to 140° C., even more preferably from 70° C. to 130° C. When the 10-hour half-life temperature is within the range described above, the curing is unlikely to be deficient, and thus the adhesive residue can be inhibited.

The numerical value of the 10-hour half-life temperature of the radical polymerization initiator can be obtained from literatures, and catalogs of manufacturers and the like may be referenced. For example, the catalog values of NOF Corporation (http://www.nof.co.jp/upload_public/sogo/B0100.pdf) and the like may be referenced.

Specific examples of photoradical polymerization initiators that can be used include 2,2-dimethoxy-1,2-diphenylethan-1-one, 1-hydroxy-cyclohexyl-phenyl-ketone, 1-[4-(2-hydroxyethoxy)-phenyl]-2-hydroxy-2-methyl-1-propan-1-one, 2-methyl-1-[4-(methylthio)phenyl]-2-morpholinopropan-1-one, 2-benzyl-2-dimethylamino-1-(4-morpholinophenyl)-1-butanone, bis(2,4,6-trimethylbenzoyl)-phenylphosphine oxide, 2-hydroxy-1-{4-[4-(2-hydroxy-2-methyl-propionyl)-benzyl]-phenyl}-2-methyl-propane, 1,2-octanedione, 1-[4-(phenylthio)-2-(O-benzoyloxime)], 2-hydroxy-2-methyl-1-phenyl-propan-1-one, phenylglyoxylic acid methyl ester, and 2,4,6-trimethylbenzoyl-diphenyl-phosphine oxide.

The compounds described above may be available as commercially available products, and examples thereof include OMNIRAD 1000, OMNIRAD 248, OMNIRAD 481, OMNIRAD 4817, OMNIRAD 4MBZ-flakes, OMNIRAD 500, OMNIRAD 659, OMNIRAD 73, OMNIRAD 784, OMNIRAD 81, OMNIRAD BDK, OMNIRAD MBS, OMNIRAD BP-flakes, OMNIRAD DETX, OMNIRAD EDB, OMNIRAD EHA, OMNIRAD EMK, OMNIRAD ITX, OMNIRAD MBF, OMNIRAD OMBB, OMNIRAD TPO, OMNIRAD 410, OMNIRAD BL723, OMNIRAD BL724, OMNIRAD BL750, OMNIRAD BL751, OMNIRAD 1173, OMNIRAD 127, OMNIRAD 184, OMNIRAD 184FF, OMNIRAD 2022, OMNIRAD 2100, OMNIRAD 2959, OMNIRAD 369, OMNIRAD 369E, OMNIRAD 379, OMNIRAD 379EG, OMNIRAD 4265, OMNIRAD 754, OMNIRAD 819, OMNIRAD 819DW, OMNIRAD 907, OMNIRAD 907FF, OMNIRAD BP, OMNIRAD 127D, ESACURE 1001M, ESACURE ONE, ESACURE A198, ESACURE KIP 160, ESACURE KIP 150, ESACURE KIP100F, ESACURE KIP-LT, ESACURE KIP-IT, ESACURE KTO-46, ESACURE DP-250, ESACURE TZT, and ESACURE KT-55 (manufactured by IGM Resins B.V.).

With respect to the ratio of the amount of the curing agent (B1) to the amount of the curing agent (B2), a larger amount of the curing agent (B1) is not technically disadvantageous. From the viewpoint of the costs, the ratio of the curing agent (B1)/curing agent (B2) is preferably 100 or less, more preferably 30 or less, markedly preferably 10 or less, particularly preferably 5 or less. Since a degree of curing at which flattening easily occurs is likely to be achieved and the processing period can be shortened during flattening processing, the ratio of the curing agent (B1)/curing agent (B2) is preferably 1 or more, more preferably 3 or more, even more preferably 5 or more, markedly preferably 10 or more.

When the curing agent (B1) is a thermal radical polymerization initiator, and the curing agent (B2) is a photoradical polymerization initiator, the ratio of the amount of the thermal radical polymerization initiator:the amount of photoradical polymerization initiator is the same as described above. When the ratio of the thermal radical polymerization initiator:photoradical polymerization initiator is within the range described above, curing by the photoradical polymerization initiator easily proceeds first, and a hard adhesive layer in a certain amount is formed. Thereafter, curing by the thermal radical polymerization initiator proceeds, an adhesive layer having small variations in the height of the adhesive can be formed while the planarity is maintained.

The amount of the curing agents (that is, the total of the curing agent (B1) and curing agent (B2)) contained in the resin composition can be from 0.01 to 10 parts by mass, for example, based on 100 parts by mass of the curable polymer (A). In order to achieve more reliable curing, the amount of the curing agents (that is, the total of the curing agent (B1) and curing agent (B2)) contained in the resin composition is preferably 0.01 mass % or more, even more preferably 0.05 mass % or more, particularly preferably 0.10 mass % or more. In order to reduce the amount of outgassing derived from curing agent (B), the amount of the curing agents (that is, the total of the curing agent (B1) and curing agent (B2)) contained in the resin composition is preferably 10 parts by mass or less, even more preferably 5 parts by mass or less, particularly preferably 1 part by mass or less.

[Crosslinking Agent (C)]

The resin composition according to the present disclosure may further comprise a crosslinking agent (C).

The crosslinking agent (C) is a component that enables a crosslinking structure to be formed by heating in the curable polymer (A). When the resin composition further comprises the crosslinking agent (C), an adhesive layer having a crosslinking structure can be formed.

The crosslinking agent (C) is preferably a compound having a polyfunctional carbon-carbon multiple bond, particularly preferably a polyfunctional (meth)acrylate.

The polyfunctional (meth)acrylate is not particularly limited as long as having 2 or more and 10 or less (meth)acryloyl groups, and preferably has 2 or more and 6 or less (meth)acryloyl groups.

Specific examples of the polyfunctional (meth)acrylate to be used as the crosslinking agent (C) can include the following compounds: alkyl di(meth)acrylate, hydroxyl group-containing alkyl di(meth)acrylate, polyalkylene glycol di(meth)acrylate, dioxane di(meth)acrylate, tricyclodecanol di(meth)acrylate, fluorene di(meth)acrylate, alkoxylated bisphenol A di(meth)acrylate, (alkoxylated)trimethylolpropane di(meth)acrylate, (alkoxylated)trimethylolpropane tri(meth)acrylate, alkoxylated serine di(meth)acrylate, (caprolactone-modified)isocyanurate tri(meth)acrylate, (alkoxylated)pentaerythritol di(meth)acrylate, pentaerythritol tri(meth)acrylate, pentaerythritol tetra(meth)acrylate, alkoxylated pentaerythritol di(meth)acrylate, (alkoxylated)ditrimethylolpropane di(meth)acrylate, (alkoxylated)ditrimethylolpropane tri(meth)acrylate, (alkoxylated)ditrimethylolpropane tetra(meth)acrylate, (alkoxylated)dipentaerythritol di(meth)acrylate, (alkoxylated)dipentaerythritol tri(meth)acrylate, (alkoxylated)dipentaerythritol tetra(meth)acrylate, (alkoxylated)dipentaerythritol penta(meth)acrylate, and (alkoxylated)dipentaerythritol hexa(meth)acrylate.

Preferable examples of the polyfunctional acrylate compound also include polyethylene glycol #400 diacrylate (NK Ester A-400 (molecular weight: 508)), polyethylene glycol #600 diacrylate (NK Ester A-600 (molecular weight: 742)), A-DOD-N, A-BPE-10, A-GLY-9E, A-9300, A-9300-1CL, and AD-TMP-L manufactured by Shin Nakamura Chemical Co., Ltd.

The crosslinking agent (C) is more preferably a bifunctional or higher (meth)acrylate curing agent containing 2 or more and 10 or less acrylate groups per molecule. Specific examples of such compounds can include glycerol propyl-added tri(meth)acrylate, ditrimethylol tetra(meth)acrylate, and dipentaerythritol penta(meth)acrylate.

The content of the carbon-carbon multiple bond included in the crosslinking agent (C) is not particularly limited, and the multiple bond equivalent thereof is preferably 60 g/mol or more and 1,000 g/mol or less, more preferably 80 g/mol or more and 900 g/mol or less, even more preferably 100 g/mol or more and 700 g/mol or less, even more preferably 200 g/mol or more and 400 g/mol or less.

The multiple bond equivalent can be determined by the method mentioned above in relation with the curable polymer (A).

The amount of the crosslinking agent (C) contained is preferably 0 part by mass or more and 20 parts by mass or less, more preferably 0.5 parts by mass or more and 5 parts by mass or less based on 100 parts by mass of the curable polymer (A). When the content of the crosslinking agent (C) is within the range described above, the adhesive residue further can be inhibited.

[Other Components]

The resin composition according to the present disclosure may contain other optional components in addition to the components described above. Examples of optional components include an antioxidant, an antiaging agent, an ultraviolet absorber, a light stabilizer, a defoamer, a leveling agent, an antistatic agent, a surfactant, a preservative stabilizer, a thermal polymerization inhibitor, a plasticizer, a wettability improver, an adherence imparting agent, a tackifier, and an organic solvent. These optional components may be added singly, or two or more thereof may be added.

These optional components are only required to be added in an amount that does not compromise the effects of the present disclosure. For example, the amount thereof contained is 0 part by mass or more and 10 parts by mass or less based on 100 parts by mass of the total mass of the resin composition.

[Method for Producing Cured Product]

The method for producing the above-described cured product that forms the adhesive layer of the pellicle is not particularly limited, and the cured product can be produced by a method known as a method for producing a cured product that forms an adhesive layer. For example, the curable polymer (A), curing agents (B1) and (B2), mentioned above, and, if desired, a crosslinking agent (C), an organic solvent, and other components are mixed in the amounts contained mentioned above to obtain a resin composition. Curing a solution of the adhesive enables the cured product described above to be obtained.

Curing the resin composition according to the present disclosure enables the cured product described above to be obtained. For the curing method and the like, refer to the following method for producing a pellicle.

2. Method for Producing Pellicle

The pellicle of the present disclosure can be produced by a method including the following processes of:

1) stretching a pellicle membrane over one end surface of a pellicle frame,

2) applying a resin composition comprising at least a curable polymer (A), a curing agent (B1), and a curing agent (B2) on the other end surface of the pellicle frame, and

3) subjecting the applied resin composition to curing treatment of the curing agent (B1) and curing treatment of the curing agent (B2), and flattening treatment to thereby provide an adhesive layer.

The pellicle of the present disclosure can be produced in the same manner as for conventional pellicles except that a resin composition comprising at least 2 curing agents is used to provide the adhesive layer in process 2) and that a 2-stage curing process is performed in process 3). When 3 or more curing agents that each perform curing under different conditions are used, a 3-stage or more curing process can be performed under conditions suitable for curing by each of the curing agents.

Process 1) in the method for producing the pellicle may be performed before process 2) or may be performed after process 3); provided that process 3) shall be performed certainly after process 2).

In a preferable aspect of the method for producing the pellicle of the present disclosure, the resin composition used in process 2) comprises a curable polymer (A), and a curing agent (B1) as a thermal radical polymerization initiator and a curing agent (B2) as a photoradical polymerization initiator, and photocuring treatment and thermal curing treatment, and flattening treatment are performed in process 3).

The curing treatment may be a known method, and may be photocuring treatment, thermal curing treatment, and radiation curing treatment, for example.

Process 1)

A pellicle membrane is stretched over one opening of a pellicle frame. Stretching over the pellicle membrane can be performed by a usual method. For example, it is only required that an adhesive usually used be applied on one end surface of the pellicle frame to form an adhesive layer and the pellicle membrane be fixed on the adhesive layer.

The adhesive may be a known one, and may be a cellulose derivative, chlorinated polypropylene, a polyamide adhesive, a fluorine resin adhesive, an acrylic adhesive, an epoxy resin, a polyimide adhesive, or the like.

Process 2)

Next, a resin composition comprising a curable polymer (A), a curing agent (B1), and a curing agent (B2) is applied on the other end surface of the pellicle frame.

The resin composition can be produced by a method known as a method for producing an adhesive. For example, the curable polymer (A) and the curing agent (B1) and the curing agent (B2) mentioned above, and, if desired, a crosslinking agent (C), an organic solvent, and other components are mixed in the amounts contained mentioned above to enable the resin composition described above to be obtained.

The resin composition can be applied as is to the pellicle frame, or other components may be added to the resin composition to prepare a coating solution. The coating solution may further comprise an organic solvent along with the resin composition. Specific examples of the solvent include the following compounds:

aromatic solvents such as toluene and xylene; ketone solvents such as acetone, methyl ethyl ketone, methyl isobutyl ketone, and 2-methyl-5-hexanone; ester solvents such as ethyl acetate and butyl acetate; halogen solvents such as methyl chloride, dichloromethane, and dichloroethane;

glycol ether solvents such as ethylene glycol monoethyl ether, propylene glycol monomethyl ether, and propylene glycol mono n-propyl ether; and

glycol ether carboxylate solvents such as propylene glycol monomethyl ether acetate.

The organic solvents may be used singly or in admixture of two or more thereof.

The boiling point of the organic solvent (that is, for one solvent, the boiling point of the solvent used, and for 2 or more solvents, the boiling point of the mixture) is preferably 150° C. or less. The thermal decomposition onset temperature of a (meth)acrylic acid ester copolymer used as one example of the curable polymer (A) is around 150° C. Thus, when the boiling point of the organic solvent used is 150° C. or less, the organic solvent can be removed without heating to around 150° C., at which the (meth)acrylic acid ester copolymer may be decomposed.

The amount of the organic solvent contained is not particularly limited, and is usually preferably 0 part by mass or more and 90 parts by mass or less, more preferably 0 part by mass or more and 50 parts by mass or less based on 100 parts by mass of the total mass of the coating solution.

The above-described resin composition or coating solution can be applied by use of any application approach and can be applied by, for example, a spray application method, a dipping application method, a brush application method, a spatula application method, a roller coat method, a flow coating method, or the like. In the flow coating method, for example, after a droplet is dropped on the surface of a pellicle frame, the drop is extended by a jig to enable application at a uniform thickness to be achieved. The thickness of the coating film formed here is not particularly limited and is usually 0.2 mm or more and 0.8 mm or less.

Process 3)

The coating film formed by applying the resin composition on the pellicle frame are subjected to curing treatment of the curing agent (B1) and curing treatment of the curing agent (B2), and flattening treatment to thereby provide an adhesive layer. For example, when the curing agent (B1) is a thermal radical polymerization initiator and the curing agent (B2) is a photoradical polymerization initiator, photocuring treatment and thermal curing treatment, and flattening treatment are performed in process 3).

The above-described resin composition after application also can be dried before the treatment for curing is performed. The drying can be performed under heating conditions of a temperature of 40° C. to 110° C. for 5 minutes to 60 minutes.

For example, photocuring treatment, thermal curing treatment, and flattening treatment are performed on the dried coating film. The order in which the photocuring treatment, thermal curing treatment, and flattening treatment are performed is not particularly limited. The thermal curing treatment may be performed after the photocuring treatment, or the photocuring treatment may be performed after the thermal curing treatment. However, it is desirable that the coating film be pre-cured by the photocuring treatment first and then the coating film be completely cured by thermal curing. The flattening treatment can be performed simultaneously with the photocuring treatment and/or thermal curing treatment.

The photocuring treatment is desirably performed under conditions that satisfy the curing conditions for the photoradical polymerization initiator contained as the curing agent (B2). The wavelength used for the photocuring treatment is preferably from 254 nm to 365 nm, and the treatment period is preferably from 10 minutes to 30 minutes. In such photocuring treatment, a constant amount of light irradiation can be achieved, and thus the cured portion in the coating film is easily made uniform.

The thermal curing treatment is desirably performed under conditions that satisfy the curing conditions for the thermal radical polymerization initiator contained as the curing agent (B1). The temperature used for the thermal curing treatment is preferably from 40° C. to 170° C., and the treatment period is preferably from 10 minutes to 2,880 minutes. Such thermal curing treatment provides an adhesive of the resin composition cured.

Performing the photocuring treatment under heating enables the thermal curing treatment to be performed simultaneously with the photocuring treatment. For example, starting the photocuring treatment under heating and continuing heating after completion of the photocuring treatment also enables the thermal curing treatment to be continuously performed.

The flattening treatment is a treatment that adjusts the thickness of the adhesive layer including the above-described cured product as well as enhances the flatness thereof. The pellicle can be flattened, for example, by sandwiching a pellicle frame (or pellicle) provided with a coating film of a pressure-adhesive solution into a surface plate having a high flatness, by processing the pellicle placed in a mold, or by its own weight alone. The flattening treatment can be performed also simultaneously with the photocuring treatment and/or thermal curing treatment mentioned above. For example, heating the coating film with a flat glass plate pressed against the coating film enables the thermal curing treatment and flattening treatment to be simultaneously performed.

Before the flattening treatment described above is performed, a protective film also may be attached to the adhesive provided on the pellicle frame. Examples of the protective film that can be used include polyester films and polyethylene films subjected to release treatment with silicone or fluorine.

The flatness of the adhesive layer obtained after the flattening process is usually from 20 μm to 1 μm, preferably from 10 μm to 1 μm. As for the flatness, the height of the adhesive layer is measured at intervals of 0.3 mm over the entire circumference thereof, and the difference in height is determined from the measurements (difference in height between the highest point and the lowest point from the reference point). The difference is taken as the flatness. As for the flatness in the present disclosure, measurement results obtained by a Fizeau-type oblique incidence interferometric flatness measurement apparatus (manufactured by Corning Tropel Corporation, apparatus name: “FlatMaster”) are specified as the flatness.

Fizeau-type oblique incidence interferometry is performed under the following conditions.

Wavelength: 635 nm, fringe sensitivity: 8.28 μm

The thickness of the adhesive layer is not particularly limited, and is generally 0.2 mm or more and 0.8 mm or less. From the viewpoint of enabling the layer to be uniformly attached to the mask, the thickness is preferably 0.1 mm or more. The pellicle metal frame is hard and unlikely to be deformed. Thus, when the adhesive layer is made thicker, the metal frame can be made thinner, and the flatness of the entire pellicle is believed to be improved.

In order to inhibit outgassing by the adhesive layer, volatile components can be removed. For example, the volatile components can be removed by heat-drying the pellicle under conditions under which the adhesive layer or the pellicle membrane does not deteriorate, for example, at 150° C. for 4 hours or at 120° C. for 20 hours.

3. Uses of Pellicle

The pellicle thus obtained is mounted on a mask with the above-described adhesive layer interposed therebetween. This may prevent attachment of foreign matter to the mask. Foreign matter attached to the mask, when exposure light is focused thereon, causes resolution deficiency onto the wafer. For this reason, the pellicle is mounted so as to cover the exposure area of the mask.

A mask is a glass substrate or the like including a patterned light shielding membrane disposed thereon. A light shielding membrane may be a membrane of a metal such as Cr or MoSi.

Then, exposure light enters a portion other than the light shielding membrane of the mask, penetrating the pellicle membrane. Exposure light usually enters in substantially parallel to the normal line of the pellicle membrane, but may enter obliquely to the normal line of the pellicle membrane.

Examples of exposure light for use in lithography such as a process for forming a circuit pattern to be drawn on a semiconductor device may include a mercury lamp i line (wavelength: 365 nm), and short-wavelength excimer light such as KrF excimer laser (wavelength 248 nm) and ArF excimer laser (wavelength 193 nm).

As mentioned above, in the present disclosure, incorporation of at least 2 curing agents in the adhesive layer of the pellicle allows the flatness of the adhesive layer to be improved. As a result, distortion of the mask including the pellicle mounted thereon is reduced, and displacement of the exposure position is also reduced.

### EXAMPLES

Hereinafter, the content of the present disclosure will be more concretely described with reference to examples, but the contents of the present disclosure is not construed to be limited to these example.

1. Materials

In the following Examples and Comparative Examples, materials described below were used.

1-1. Curable Polymer (A)

RA-341: “ART CURE RA-341” manufactured by Negami Chemical Industrial Co., Ltd. (multiple bond equivalent: 13,000 g/mol, weight average molecular weight: 80,000)

1-2. Curing Agent (B1)

Thermal radical polymerization initiator: “Perkadox 12-XL25” manufactured by Kayaku Nouryon Corporation

1-3. Curing Agent (B2)

Photoradical polymerization initiator: “Omnirad 1173” manufactured by BASF SE

2. Production of Pellicle

### Example 1

RA-341 (solid concentration: 100%), which is a (meth)acrylic acid ester copolymer, was used as the curable polymer (A). To 100 parts by mass of RA-341, 4 parts by mass of a thermal radical polymerization initiator (peroxide radical polymerization initiator, solid concentration: 25%) as the curing agent (B1) and 0.01 parts by mass of a photoradical polymerization initiator as the curing agent (B2) were added. Stirring at room temperature provided a resin composition 1 having a solid concentration ratio of the curable polymer (A):curing agent (B1):curing agent (B2)=100:1:0.01.

To an end surface of a pellicle frame made of aluminum subjected to anodization (outer dimension: 149 mm×122 mm, frame height: 5.8 mm, frame width: 2 mm), the resin composition 1 was applied using a dispenser at an application temperature of 60° C. This was heat-dried (60° C., 30 minutes) to obtain a coating film. Photocuring treatment was performed with the irradiation quantity adjusted so as to achieve a dosage to the coating film obtained of 410 mJ/cm². Thereafter, a separator made of PET was stuck to the coating film subjected to the photocuring treatment. In order to obtain an adhesive layer having a separator, heat curing treatment (120° C./30 minutes) was performed while a flat glass plate was pressed against the separator.

As a result, there obtained was a pellicle having an adhesive layer of 375 μm in thick.

### Examples 2 to 3

Resin compositions were prepared in the same manner as in Example 1 except that the amount of each of the components was changed such that the solid concentration ratio of the curable polymer (A):curing agent (B1):curing agent (B2) of each of the resin compositions would correspond to the value shown in Table 1 to thereby obtain resin compositions 2 and 3.

Each of the resin compositions obtained was used to form an adhesive layer on an end surface of the pellicle frame in the same manner as in Example 1 to thereby obtain a pellicle.

### Comparative Example 1

Mixing was performed in the same manner as in Example 1 except that the curing agent (B2) was not used to thereby obtain a resin composition 4.

To an end surface of a pellicle frame made of aluminum subjected to anodization (outer dimension: 149 mm×122 mm, frame height: 5.8 mm, frame width: 2 mm), the resin composition 1 was applied using a dispenser at an application temperature of 60° C. This was heat-dried (60° C., 30 minutes) to obtain a coating film. A separator made of PET was stuck to the coating film obtained. In order to obtain an adhesive layer having a separator, heat curing treatment (120° C./30 minutes) was performed while a flat glass plate was pressed against the separator.

4. Evaluation Method

4-1. State of Adhesive Layer

The adhesive layer after the flattening treatment was visually observed, and the state of the adhesive layer was evaluated in accordance with the following criteria.

B: A protrusion of the adhesive layer outside the pellicle frame is observed.

A: No protrusion of the adhesive layer outside the pellicle frame is observed.

4-2. Flatness

The flatness was measured by Tropel measurement. Each of the pellicles produced in Examples and Comparative Example was used as a specimen (outer dimension: 149 mm×122 mm, frame height H: 5.8 mm, and frame width W: 2 mm). The specimen was placed on a Fizeau-type oblique incidence interferometric flatness measurement apparatus (manufactured by Corning Tropel Corporation, apparatus name: “FlatMaster”), and the difference in height was measured under conditions including wavelength: 635 nm and fringe sensitivity: 8.28 μm. As for the flatness, the height of the adhesive layer was measured at intervals of 0.3 mm over the entire circumference thereof, and the difference in height was determined from the measurements (difference in height between the highest point and the lowest point from the reference point). The difference was taken as the flatness.

The evaluation results are shown in Table 1 along with the composition of the adhesive layer (solid concentration ratio of the curable polymer (A):curing agent (B1):curing agent (B2)) and the conditions for the photocuring treatment.

TABLE 1

| | | | | | Comparative |
|---|---|---|---|---|---|
| | | Example 1 | Example 2 | Example 3 | Example 1 |
| Curable polymer (A) | | 100 | 100 | 100 | 100 |
| Curing agent (B1) | | 1 | 1 | 0.5 | 1 |
| Curing agent (B2) | | 0.01 | 0.02 | 0.05 | 0 |
| Photocuring treatment | | 410 | 327 | 205 | 0 |
| conditions (UV | | | | | |
| irradiation quantity, | | | | | |
| mJ/cm²) | | | | | |
| Evaluation | State of | A | A | A | B |
| results | adhesive | | | | |
| | layer | | | | |
| | Flatness | 7 | 10 | 9 | Not |
| | (μm) | | | | measurable |
| | | | | | because the |
| | | | | | adhesive was |
| | | | | | outside the |
| | | | | | frame |

As obviously seen from Table 1 above, in the adhesive layers of Examples 1 to 3, which include the curable polymer (A) and curing agents (B1) and (B2), no protrusion outside the frame after the flattening treatment was observed, and the flatness was as favorable as 10 μm or less.

In contrast, in the adhesive layer of Comparative Example 1, which comprises only the curable polymer (A) and curing agent (B1), the major part of the adhesive after the flattening treatment protruded outside the frame, and thus the flatness could not be measured.

The present application claims the benefit of Japanese Patent Application Laid-Open No. 2020-057395, filed on Mar. 27, 2020. The contents of the appended claims and the description of the application are incorporated herein by reference.

### INDUSTRIAL APPLICABILITY

Disclosed are a pellicle that includes an adhesive layer having favorable flatness, and a method for producing the pellicle with high reproducibility. When the pellicle of the present disclosure is used, distortion of a mask is reduced, and also, displacement of the exposure position is more unlikely to occur. According to the method for producing the pellicle of the present disclosure, it is possible to produce a pellicle that includes an adhesive layer having favorable flatness with a high yield.

1. A pellicle, comprising:
a pellicle frame;
a pellicle membrane stretched over one end surface of the pellicle frame; and
an adhesive layer provided on another end surface of the pellicle frame, wherein
the adhesive layer comprises a cured product of a resin composition comprising a curable polymer (A), a curing agent (B1), and a curing agent (B2) different from the curing agent (B1).

2. The pellicle according to claim 1, wherein the curing agent (B1) and the curing agent (B2) are radical polymerization initiators.

3. The pellicle according to claim 2, wherein the curing agent (B1) is a thermal radical polymerization initiator, and the curing agent (B2) is a photoradical polymerization initiator.

4. The pellicle according to claim 3, wherein the thermal radical polymerization initiator is a peroxide radical polymerization initiator or azo radical polymerization initiator.

5. The pellicle according to claim 1, wherein the curable polymer (A) is at least one curable polymer selected from the group consisting of a (meth)acrylic acid ester copolymer (A-1), an organopolysiloxane (A-2), and a polyurethane polyol (A-3).

6. The pellicle according to claim 5, wherein the curable polymer (A) is a (meth)acrylic acid ester copolymer.

7. The pellicle according to claim 1, wherein the curable polymer (A) has a side chain containing a carbon-carbon multiple bond-containing group.

8. The pellicle according to claim 7, wherein the carbon-carbon multiple bond-containing group is a carbon-carbon double bond-containing group.

9. The pellicle according to claim 7, wherein a multiple bond equivalent of the curable polymer (A) is 156 g/mol or more and 100,000 g/mol or less.

10. The pellicle according to claim 1, wherein the curable polymer (A) has a weight average molecular weight of 10,000 or more and 1,000,000 or less.

11. The pellicle according to claim 1, wherein the resin composition further comprises a crosslinking agent (C).

12. The pellicle according to claim 11, wherein the crosslinking agent (C) is a compound having a polyfunctional carbon-carbon multiple bond.

13. A method for producing the pellicle according to claim 1, comprising:
stretching a pellicle membrane over one end surface of a pellicle frame;
applying a resin composition comprising a curable polymer (A), a curing agent (B1); and a curing agent (B2) different from the curing agent (B1) on another end surface of the pellicle frame; and
subjecting the applied resin composition to photocuring treatment and thermal curing treatment, and flattening treatment to thereby provide an adhesive layer.
